(19) United States
(12) Patent Application Publication
(10) Pub. No.: US 2025/0309886 A1
(43) Pub. Date: Oct. 2, 2025

(54) GATE DRIVING UNIT

(71) Applicant: Monolithic Power Systems, Inc., Kirkland, WA (US)

(72) Inventors: Di Han, San Jose, CA (US); Jian Jiang, Saratoga, CA (US)

(21) Appl. No.: 18/618,365

(22) Filed: Mar. 27, 2024

(51) Int. Cl. H03K 17/082

(52) U.S. Cl. CPC H03K 17/0822

(57) ABSTRACT

A gate driving unit having a first terminal adapted to be configured as a control terminal, a second terminal adapted to be configured as a reference ground terminal and a third terminal adapted to be configured as an output terminal. The gate driving unit may receive a pulse width modulated signal at the first terminal and provide a switch driving signal at the third terminal. The gate driving unit may detect or monitor a current signal flowing through the third terminal and control a logic state of the switch driving signal based on the pulse width modulated signal and the current signal.

### TECHNICAL FIELD

This disclosure relates generally to electronic circuits, and more particularly but not exclusively relates to gate drivers for switching devices.

### BACKGROUND

In power converter applications, gate drivers are generally used to drive power switches, such as power metal-oxide semiconductor field effect transistor (MOSFET), insulated gate bipolar transistor (IGBT), etc. Isolated gate drivers are popular in power conversion or power management applications for handling high power or high voltage. Most widely used isolated gate drivers come in a compact and low cost SOIC8 package, but those drivers cannot provide monitoring or protection features.

### SUMMARY

There has been provided, in accordance with an embodiment of the present disclosure, a gate driving unit having a first terminal adapted to be configured as a control terminal, a second terminal adapted to be configured as a reference ground terminal and a third terminal adapted to be configured as an output terminal. The gate driving unit may be adapted to receive a pulse width modulated signal at the first terminal and to provide a switch driving signal at the third terminal. The gate driving unit may detect or monitor a current signal flowing through the third terminal and control a logic state of the switch driving signal based on the pulse width modulated signal and the current signal.

There has also been provided, in accordance with an embodiment of the present disclosure a gate driving unit having a first terminal adapted to be configured as a control terminal, a second terminal adapted to be configured as a reference ground terminal and a third terminal adapted to be configured as an output terminal of the gate driving unit. The gate driving unit may further include a driver adapted to generate and provide a switch driving signal to the third terminal and a driver control circuit coupled between the first terminal and the driver. The driver control circuit may be adapted to be configured to receive a pulse width modulated signal from the first terminal, and further configured to detect or monitor a feedback signal indicative of a current signal flowing through the third terminal, and further configured to control a logic state of the switch driving signal based on the pulse width modulated signal and the current signal.

There has also been provided, in accordance with an embodiment of the present disclosure a gate driving unit having a first terminal adapted to be configured as a control terminal to receive a pulse width modulated signal, a second terminal adapted to be configured as a reference ground terminal, a third terminal adapted to be configured as an output terminal of the gate driving unit for providing a switch driving signal, and a reporting terminal adapted to provide a reporting signal. The pulse width modulated signal may have a set logic state and a reset logic state. The switch driving signal may have a logic state including a driving set logic state and a driving reset logic state. The gate driving unit may detect or monitor a current signal flowing through the third terminal, and may be adapted to control the logic state of the switch driving signal based on the pulse width modulated signal and the current signal. The gate driving unit may further be adapted to set the reporting signal to a first report status or to a second report status based on the pulse width modulated signal and the current signal.

### BRIEF DESCRIPTION OF DRAWINGS

The following detailed description of various embodiments of the present invention can best be understood when read in conjunction with the following drawings, in which the features are not necessarily drawn to scale but rather are drawn as to best illustrate the pertinent features.

FIG. 1 schematically illustrates a gate driving unit 100 in accordance with an embodiment of the present disclosure.

FIG. 2 illustrates a waveform diagram 200 showing waveforms of several signals of the gate driving unit 100 in accordance with an exemplary embodiment of the present disclosure.

FIG. 3 illustrates a block diagram of a power conversion apparatus 300 in accordance with an embodiment of the present disclosure.

FIG. 4 illustrates a waveform diagram 400 showing waveforms of several signals of the gate driving unit 100 in accordance with an alternative exemplary embodiment of the present disclosure.

FIG. 5 illustrates a waveform diagram 500 showing waveforms of several signals of the gate driving unit 100 in accordance with still an alternative exemplary embodiment of the present disclosure.

FIG. 6 illustrates an exemplary schematic diagram of a gate driving unit 600 in accordance with an exemplary embodiment of the present disclosure.

FIG. 7 illustrates an exemplary schematic diagram of a gate driving unit 700 in accordance with an exemplary embodiment of the present disclosure.

FIG. 8 illustrates a waveform diagram 800 showing waveforms of several signals of the gate driving unit 700 in accordance with an exemplary embodiment of the present disclosure.

FIG. 9 schematically illustrates a gate driving unit 900 in accordance with an embodiment of the present disclosure.

FIG. 10 schematically illustrates a gate driving unit 1000 in accordance with an embodiment of the present disclosure.

FIG. 11 schematically illustrates a gate driving unit 1100 in accordance with an embodiment of the present disclosure.

FIG. 12 illustrates a waveform diagram 1200 showing waveforms of several signals of a gate driving unit including a reporting terminal in accordance with an exemplary embodiment of the present invention.

### DETAILED DESCRIPTION

Various embodiments of the present invention will now be described. In the following description, some specific details, such as example circuits and example values for these circuit components, are included to provide a thorough understanding of embodiments. One skilled in the relevant art will recognize, however, that the present invention can be practiced without one or more specific details, or with other methods, components, materials, etc. In other instances, well-known structures, materials, processes or operations are not shown or described in detail to avoid unnecessarily obscuring aspects of the present invention. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims.

Reference to “one embodiment”, “an embodiment”, “an example” or “examples” means: certain features, structures, or characteristics are contained in at least one embodiment of the present invention. These “one embodiment”, “an embodiment”, “an example” and “examples” are not necessarily directed to the same embodiment or example, although it may. Furthermore, the features, structures, or characteristics may be combined in one or more embodiments or examples. In addition, it should be noted that the drawings are provided for illustration, and are not necessarily to scale. Throughout the specification and claims, The term “coupled,” as used herein, is defined as directly or indirectly connected in an electrical or non-electrical manner. And when an element is described as “connected” or “coupled” to another element, it can be directly connected or coupled to the other element, or there could exist one or more intermediate elements. In contrast, when an element is referred to as “directly connected” or “directly coupled” to another element, there is no intermediate element. The terms “a,” “an,” and “the” include plural reference, and the term “in” includes “in” and “on” unless the context clearly dictates otherwise. The term “or” is an inclusive “or” operator, and is equivalent to the term “and/or” herein including “and”, “or” and any combination thereof, unless the context clearly dictates otherwise. Where either a field effect transistor (“FET”) or a bipolar junction transistor (“BJT”) may be employed as an embodiment of a transistor, the scope of the words “gate”, “drain”, and “source” includes “base”, “collector”, and “emitter”, respectively, and vice versa. Those skilled in the art should understand that the meanings of the terms identified above do not necessarily limit the terms, but merely provide illustrative examples for the terms.

The terms “comprise”, “include”, “have” and any variations thereof, are intended to cover non-exclusive inclusions, such that a process, method, article, or apparatus that comprises a list of elements is not necessarily limited to those elements, but may include other elements not expressly listed or inherent to such process, method, article, or apparatus.

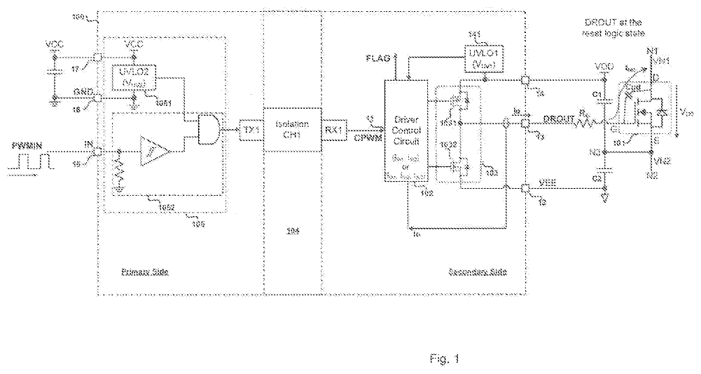

FIG. 1 schematically illustrates a gate driving unit 100 in accordance with an embodiment of the present invention. The gate driving unit 100 may be adapted to be configured to drive a switching device 101. For example, when being used in power conversion applications, the gate driving unit 100 may be configured to drive the switching device 101 to perform on and off switching. The switching device 101 may include power switches such as power MOSFET, IGBT, etc. In the example of FIG. 1, the switching device 101 is illustratively shown as including a MOSFET, however this is not intended to be limiting.

In accordance with an exemplary embodiment of the present invention, the gate driving unit 100 may have a first terminal 11 that may be adapted to be configured as a control terminal or a control node, a second terminal 12 that may be adapted to be configured as a reference ground terminal of the gate driving unit 100, and a third terminal 13 that may be adapted to be configured as an output terminal of the gate driving unit 100. The first terminal 11 may be adapted to receive a pulse width modulated signal CPWM. The pulse width modulated signal CPWM may include a logic signal having a logic state including a reset logic state (e.g., logic low) and a set logic state (e.g., logic high). For ease of description and understanding, the pulse width modulated signal CPWM changes from the set logic state (e.g., logic high) to the reset logic state (e.g., logic low) may be referred to as a first type transition edge of the pulse width modulated signal, and the pulse width modulated signal CPWM changes from the reset logic state (e.g., logic low) to the set logic state (e.g., logic high) may be referred to as a second type transition edge of the pulse width modulated signal herein after in the present disclosure.

The third terminal 13 may be adapted to provide a switch driving signal DROUT, which may be used to drive the switching device 101. The switch driving signal DROUT may include a logic signal having a logic state including a driving reset logic state (e.g., logic low) that may be adapted to be configured to drive the switching device 101 OFF and a driving set logic state (e.g., logic high) that may be adapted to be configured to drive the switching device 101 ON. For ease of description and understanding, a time or a moment when or at which the switch driving signal DROUT is changed (or is reset) from the driving set logic state (e.g., logic high) to the driving reset logic state (e.g., logic low) may be referred to as a reset moment and a time or a moment when or at which the switch driving signal DROUT is changed (or is set) from the driving reset logic state (e.g., logic low) to the driving set logic state (e.g., logic high) may be referred to as a set moment herein after in the present disclosure. The switch driving signal DROUT may have a switching cycle Tsw which may refer to a time interval between every two successively neighboring reset moments of the switch driving signal DROUT.

In accordance with an exemplary embodiment of the present invention, a driver control circuit 102 may be provided and adapted to be coupled between the first terminal 11 and a driver 103. The driver control circuit 102 may be configured to control the driver 103 to generate the switch driving signal DROUT.

In accordance with an exemplary embodiment of the present invention, the driver control circuit 102 may be configured to receive the pulse width modulated signal CPWM from the first terminal 11. The driver control circuit 102 may further be configured to detect or monitor a feedback signal indicative of a current signal Io flowing through (for example flowing in or flowing out of) the third terminal 13. Herein, the current signal Io “flowing in” the third terminal 13 may refer to the current signal Io flowing in a direction from the third terminal into the gate driving unit 100 while the current signal Io “flowing out of” the third terminal 13 may refer to the current signal Io flowing in a direction from the third terminal 13 out of the gate driving unit 100. For ease of describing embodiments of the present disclosure, a direction of the current signal Io “flowing out of” the third terminal 13 may be considered as a reference current direction. That is, a current flowing in a direction consistent with the reference current direction may be considered as a positive current while a current flowing in a direction opposite to the reference current direction may be considered as a negative current. In an embodiment, the gate driving unit 100 or the driver control circuit 102 in the gate driving unit 100 may be adapted to be further configured to control the logic state of the switch driving signal DROUT based on the pulse width modulated signal CPWM and the current signal Io. Alternatively speaking, the gate driving unit 100 may be adapted to be further configured to control the reset moment and the set moment of the switch driving signal DROUT based on the pulse width modulated signal CPWM and the current signal Io.

In accordance with an exemplary embodiment of the present invention, the driver 103 may include a first driver switch 1031 and a second driver switch 1032 coupled in series with a push-pull configuration, and a common connection of the first driver switch 1031 and the second driver switch 1032 is coupled to the third terminal 13. However, this is just to provide an example and not intended to be limiting.

In accordance with an exemplary embodiment of the present invention, when the gate driving unit 100 is used for practical application configurations, the third terminal 13 may be coupled to a control terminal G of the switching device 101, e.g., with or without a gating resistive device RG. In an example, the gating resistive device RG may include parasitic resistances. A first terminal D of the switching device 101 may be coupled to a first power node N1 while a second terminal S of the switching device 101 may be coupled to a second power node N2. In an exemplary embodiment, the second terminal 12 of the gate driving unit 100 may be coupled to the second power node N2. The switching device 101 may sustain a voltage drop V_{DS} between the first terminal D and the second terminal S. The voltage drop V_{DS} may be indicative of a potential difference (VN1−VN2) between the first power node N1 and the second power node N2. During the switching device 101 is OFF, an electrical conduction path, for instance a current flowing path, between the first power node N1 and the second power node N2 is blocked or cut off. Once the switching device 101 is turned ON, the electrical conduction path between the first power node N1 and the second power node N2 is switched ON to allow current flowing between the first power node N1 and the second power node N2. Ideally, for switching power supply applications such as switch-mode power conversion applications, the voltage drop V_{DS} would be substantially zero during the switching device 101 is ON. Therefore, it is technically desired to switch the switching device 101 from OFF to ON when the voltage drop V_{DS} is substantially zero to reduce switching loss.

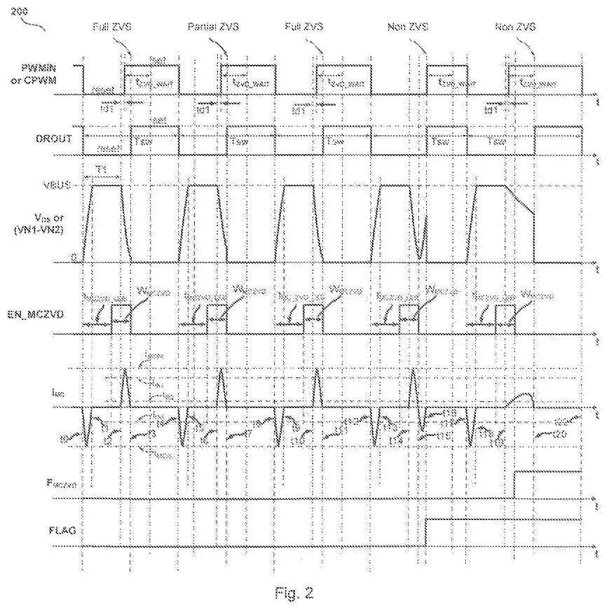

FIG. 2 illustrates waveforms of several signals of the gate driving unit 100 in accordance with an exemplary embodiment of the present invention. The gate driving unit 100 will now be described in conjunction with FIG. 1 and FIG. 2.

In accordance with an exemplary embodiment of the present invention, in each switching cycle Tsw, the gate driving unit 100 may be adapted to be configured to reset the switch driving signal DROUT to the driving reset logic state (e.g., logic low) in response to the first type transition edge of the pulse width modulated signal CPWM, i.e., in response to the pulse width modulated signal CPWM's changing from the set logic state (e.g., logic high) to the reset logic state (e.g., logic low). Let's refer to the exemplary and illustrative waveforms in FIG. 2, it is exemplarily illustrated that the switch driving signal DROUT is reset to the driving reset logic state (e.g., logic low) at a time or a moment to in response to the first type transition edge of the pulse width modulated signal CPWM. For ease of description and understanding, it may be considered that at the moment t0, the gate driving unit 100 initiates a switching cycle referred to as a present switching cycle Tsw for ease of description. Operations during the present switching cycle Tsw will be described in the following as an example.

At the reset moment t0, the switch driving signal DROUT being reset to the driving reset logic state (e.g., logic low) may be adapted to be configured to turn the switching device 101 OFF. Once the switching device 101 is off, the voltage-drop V_{DS} across the switching device 101 may start to rise up and a miller current I_{MC} may start flowing through the third terminal 13, e.g., flowing into the third terminal 13 for this situation. During the switch driving signal DROUT is at the driving reset logic state (e.g., logic low), the current signal Io may include the miller current I_{MC}. A magnitude of the miller current I_{MC} may be proportional to and thus may be indicative of a changing slope or a changing rate of the voltage-drop V_{DS}. That is |I_{MC}|=Cgd*|dV_{DS}/dt|, wherein Cgd represents a capacitance between the control terminal G and the first terminal D of the switching device 101, and dV_{DS}/dt is the mathematical expression of the changing rate of the voltage-drop V_{DS}, which is known to those skilled in the art. As illustratively shown in FIG. 2, from the reset moment t0 to a time or a moment t1 during when the voltage-drop V_{DS} is rising up, the miller current I_{MC} may flow in the third terminal 13 and thus may be illustrated as a negative current (since a direction of the current signal Io “flowing out of” the third terminal 13 is defined as a reference current direction) that firstly drops down from zero to a valley miller current value I_{MCVL} and then gradually rises back to zero.

After a first time interval T1 which begins from the reset moment t0, the voltage-drop V_{DS} across the switching device 101 may start to decrease for instance at a time or a moment t2 (i.e., T1=t2−t0). The miller current I_{MC} may again start flowing through the third terminal 13, e.g., flowing out of the third terminal 13 for this situation. In other words, the moment t2 may refer to the moment when the voltage-drop V_{DS} across the switching device 101 begins to decrease in this example, and may also be referred to as a switch-voltage decreasing starting moment. In practical applications, when the gate driving unit 100 is used for practical application configurations to drive the switching device 101 for instance to form or work at least as part of a power conversion apparatus, the voltage-drop V_{DS} across the switching device 101 may start to decrease due to switching OFF of another switch (for example may include another switching device similar as or identical to the switching device 101) which is configured to co-work with the switching device 101.

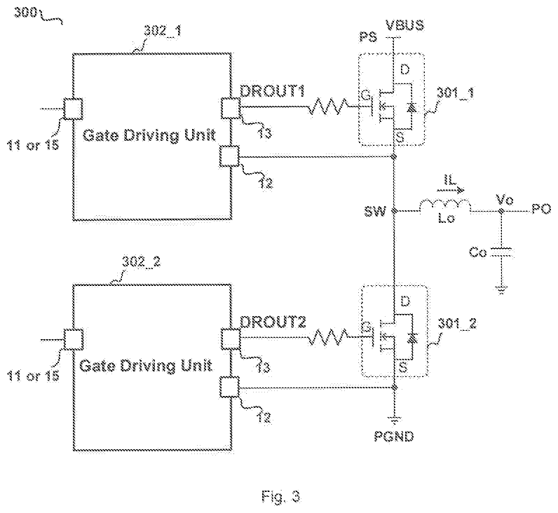

To provide an example, FIG. 3 illustrates a block diagram of a power conversion apparatus 300 in accordance with an embodiment of the present invention. The power conversion apparatus 300 may include for instance a first switch 301_1 and a second switch 301_2 coupled in series between a system power supply terminal PS and a system ground terminal PGND. The first switch 301_1 and the second switch 301_2 may have a common connection SW. A first gate driving unit 302_1 may be configured to drive the first switch 301_1. A second gate driving unit 302_2 may be configured to drive the second switch 301_2. An inductive power storage device Lo may be coupled between the common connection SW and a power conversion output terminal PO. A capacitive power storage device Co may be coupled between the power conversion output terminal PO and the system ground terminal PGND. A system supply voltage VBUS may be provided to the system power supply terminal PS. The power conversion apparatus 300 may be adapted to be configured to provide a regulated voltage Vo at the power conversion output terminal PO. In an embodiment, the gate driving unit 100 and its variants as described with various embodiments of the present disclosure may be employed to implement the first gate driving unit 302_1, and the first switch 301_1 may include a switching device similar as or identical to the switching device 101. Therefore, descriptions related to the gate driving units of various embodiments and the switching device 101 throughout the present disclosure may be applicable to the first gate driving unit 302_1 and the first switch 301_1. In an embodiment, the gate driving unit 100 and its variants as described with various embodiments of the present disclosure may be employed to implement the second gate driving unit 302_2, and the second switch 301_2 may include a switching device similar as or identical to the switching device 101. Therefore, descriptions related to the gate driving units of various embodiments and the switching device 101 throughout the present disclosure may be applicable to the second gate driving unit 302_2 and the second switch 301_2. In the example of the power conversion apparatus 300, the first switch 301_1 may be referred to as the another switch which is configured to co-work with the second switch 301_2, and vice versa. Although in the example of FIG. 3 the power conversion apparatus 300 is illustrated to have a buck power conversion topology, one of ordinary skill in the art would understand that this is just exemplary and not intended to be limiting. In alternative embodiments, the power conversion apparatus 300 may have other topology such as a boost power conversion topology, a fly-back power conversion topology, or a buck-boost power conversion topology etc.

Turning back to FIG. 1 and FIG. 2, ideally, the pulse width modulated signal CPWM may change from the reset logic state (e.g., logic low) to the set logic state (e.g., logic high) for instance also at the moment (the switch-voltage decreasing starting moment) t2. And the first time interval T1 may thus be considered as a duration or a pulse width of the reset logic state (e.g., logic low) of the pulse width modulated signal CPWM in such a particular example. However, as shown in FIG. 2, in practical applications, there may be at least a minimum time delay td1 between the switch-voltage decreasing starting moment t2 and the moment when the pulse width modulated signal CPWM changes from the reset logic state (e.g., logic low) to the set logic state (e.g., logic high) to avoid causing problems such as short-through etc. The moment when the pulse width modulated signal CPWM changes from the reset logic state (e.g., logic low) to the set logic state (e.g., logic high) may alternatively be referred to as a moment when the second type transition edge of the pulse width modulated signal CPWM comes.

As illustratively shown in FIG. 2, starting from the moment t2 as the voltage-drop V_{DS} decreasing, the miller current I_{MC} may firstly rise up from zero to a peak miller current value I_{MCPK} and then gradually fall back to be essentially at zero. Rather than turning the switching device 101 on immediately at the moment when or at which the second type transition edge of the pulse width modulated signal CPWM comes, it is generally desired to turn the switching device 101 on when the voltage-drop V_{DS} is substantially decreased to be essentially at zero to realize zero-voltage soft switching (“ZVS”) which is helpful to reduce switching loss.

In accordance with an exemplary embodiment, during the switch driving signal DROUT is at the driving reset logic state (e.g., logic low) or in response to the moment when or at which the pulse width modulated signal CPWM is changed from the reset logic state (e.g., logic low) to the set logic state (e.g., logic high), the gate driving unit 100 or its driver control circuit 102 may be configured to detect whether the voltage-drop V_{DS} across the switching device 101 is substantially decreased to be essentially at zero based on the current signal Io (or the miller current I_{MC}) flowing through the third terminal 13.

In accordance with an exemplary embodiment, the gate driving unit 100 or the driver control circuit 102 may be configured to enable or set a first zero voltage detection (“ZVD”) time window W_{MCZVD} during the switch driving signal DROUT is at the driving reset logic state (e.g., logic low) or in response to the moment when the pulse width modulated signal CPWM is changed from the reset logic state (e.g., logic low) to the set logic state (e.g., logic high). The first ZVD time window W_{MCZVD} may have a first window width or alternatively speaking a first window time duration. In an exemplary embodiment, the gate driving unit 100 or the driver control circuit 102 may be configured to detect a direction of the current signal Io flowing through the third terminal 13 during the first ZVD time window W_{MCZVD}. In an exemplary embodiment, the driver control circuit 102 may be configured to determine that (it has detected) the current signal Io is flowing out of the third terminal 13 once the current signal Io rises to or above a first predetermined threshold current value Iₜₕ₁ during the first ZVD time window W_{MCZVD}. For example, in an embodiment, the first predetermined threshold current value Iₜₕ₁ may be set to be in a range from 0.5 A to 1 A. One of ordinary skill in the art would understand that the particular range provided here is just for example and not intended to be limiting. In other embodiments, the first predetermined threshold current value Iₜₕ₁ may be set to other values according to practical application parameters.

In an exemplary embodiment, during the first ZVD time window W_{MCZVD}, the gate driving unit 100 or the driver control circuit 102 may further be configured to detect whether the current signal Io is substantially decreased to be essentially at zero after it has detected the current signal Io is flowing out of the third terminal 13. If the driver control circuit 102 has further detected the current signal Io is substantially decreased to be essentially at zero after it has detected the current signal Io is flowing out of the third terminal 13 during the first ZVD time window W_{MC_ZVD}, the driver control circuit 102 may further determine that it has identified a first detection event for instance at a time or a moment t3 as exemplarily shown in FIG. 2 during the first ZVD time window W_{MC_ZVD}. In an embodiment, when the gate driving unit 100 is used for practical application configurations to drive the switching device 101, the first detection event may indicate that the gate driving unit 100 or the driver control circuit 102 has detected that the voltage-drop V_{DS} across the switching device 101 is substantially decreased to be essentially at zero based on the current signal Io (or the miller current I_{MC}), it may also be referred to that the gate driving unit 100 or the driver control circuit 102 has identified “MCZVD” or “MCZVD” is identified. In the present disclosure, “detection of the voltage-drop V_{DS} across the switching device 101 is substantially decreased to be essentially at zero based on the current signal Io (or the miller current I_{MC}) flowing through the third terminal 13” may be referred to as “MCZVD”.

In an alternative exemplary embodiment, the gate driving unit 100 or the driver control circuit 102 may be configured to determine that it has identified the first detection event (for instance still referring to the moment t3 as exemplarily shown in FIG. 2) once the current signal Io rises to or above a first predetermined threshold current value Iₜₕ₁ and then falls back to or below a second predetermined threshold current value Iₜₕ₂ during the first ZVD time window W_{MCZVD}. The first predetermined threshold current value Iₜₕ₁ may be higher than the second predetermined threshold current value Iₜₕ₂. For example, in an embodiment, the first predetermined threshold current value Iₜₕ₁ may be set to be in a range from 0.5 A to 1 A. The second predetermined threshold current value Iₜₕ₂ may be set to be in a range from 0 A to 0.1 A. In an exemplary embodiment, the second predetermined threshold current value Iₜₕ₂ may be set based on the first predetermined threshold current value Iₜₕ₁. In an exemplary embodiment, the second predetermined threshold current value Iₜₕ₂ may be set by setting a first hysteresis between the first predetermined threshold current value Iₜₕ₁ and the second predetermined threshold current value Iₜₕ₂. One of ordinary skill in the art would understand that the particular ranges for the first predetermined threshold current value Iₜₕ₁ and the second predetermined threshold current value Iₜₕ₂ provided here are just for example and not intended to be limiting. In other embodiments, the first predetermined threshold current value Iₜₕ₁ and/or the second predetermined threshold current value Iₜₕ₂ may be set to other values according to practical application parameters. The examples for setting the second predetermined threshold current value Iₜₕ₂ based on the first predetermined threshold current value Iₜₕ₁ are also just for purpose of helping to understand the embodiments and not intended to be limiting.

In accordance with an exemplary embodiment, the gate driving unit 100 or the driver control circuit 102 may further be configured to set the switch driving signal DROUT to the driving set logic state (e.g., logic high) on condition that A) the gate driving unit 100 or the driver control circuit 102 has identified the first detection event during the first ZVD time window W_{MCZVD} and B) the pulse width modulated signal CPWM is at the set logic state (e.g., logic high), so that the switch driving signal DROUT may turn the switching device 101 ON. In this fashion, the gate driving unit 100 may be able to control the set moment of the switch driving signal DROUT based on the current signal Io (or the miller current I_{MC}) flowing through the third terminal 13 and the logic state of the pulse width modulated signal CPWM during each switching cycle Tsw. From the set moment (e.g., the moment t3 in the present switching cycle Tsw), the gate driving unit 100 or the driver control circuit 102 may keep the switch driving signal DROUT at the driving set logic state (e.g., logic high) to drive the switching device 101 being on until the switch driving signal DROUT may be reset to the driving reset logic state (e.g., logic low) again, for instance at a time or a moment t4 (which is a reset moment successively following and neighboring to the reset moment t0), for instance in response to the pulse width modulated signal CPWM's changing from the set logic state (e.g., logic high) to the reset logic state (e.g., logic low) as illustratively shown in FIG. 2.

It can be understood that following the present switching cycle Tsw lasting from the reset moment t0 to the reset moment t4 as illustratively shown in FIG. 2, at the reset moment t4, the gate driving unit 100 initiates a next switching cycle Tsw which may last from the reset moment t4 to a time or a moment t8 (i.e., a next reset moment successively following and neighboring to the reset moment t4) as illustratively shown in FIG. 2. For ease of description and understanding, the switching cycle Tsw beginning from the reset moment t0 and ending at the reset moment t4 may be referred to or denoted as Tsw (t0˜t4), and similarly the switching cycle Tsw beginning from the reset moment t4 and ending at the reset moment t8 may be referred to or denoted as Tsw (t4˜t8). One of ordinary skill in the art would understand that, during the next switching cycle Tsw (t4˜t8), there are moments t5, t6 and t7 which may be considered as respectively corresponding to the moments t1, t2 and t3 in the present switching cycle Tsw (t0˜t4) as illustratively shown in FIG. 2. One of ordinary skill in the art would further understand that operations and working principles of the gate driving unit 100 in the next switching cycle Tsw (t4˜t8) as illustratively shown in FIG. 2 may be similar or identical to those described in the present switching cycle Tsw (t0˜t4), and do not need to be addressed in detail again here. In the example of FIG. 2, more switching cycles Tsw have been illustrated out to help better understand embodiments of the present invention. For instance, a switching cycle Tsw beginning from the moment t8 to a time or a moment t12 which is a reset moment successively following and neighboring to the reset moment t8, a switching cycle Tsw beginning from the moment t12 to a time or a moment t17 which is a reset moment successively following and neighboring to the reset moment t12 and a switching cycle Tsw beginning from the moment t17 to a time or a moment t22 which is a reset moment successively following and neighboring to the reset moment t17 are exemplarily illustrated out in FIG. 2, and may respectively be referred to or denoted as Tsw (t8˜t12), Tsw (t12˜t17), and Tsw (t17˜t22) for ease of description and understanding. In each switching cycle Tsw, operations and working principles of the gate driving unit 100 may be similar or identical to those described in the present switching cycle Tsw (t0˜t4), and do not need to be addressed in detail again here.

Referring to the situations in the switching cycles Tsw (t0˜t4), Tsw (t4˜t8) and Tsw (t8˜t12) illustrated in the example of FIG. 2, for each switching cycle Tsw, if the moment when or at which the gate driving unit 100 or the driver control circuit 102 has identified the first detection event during the first ZVD time window W_{MCZVD} lays back or falls behind the moment when the pulse width modulated signal CPWM changes from the reset logic state (e.g., logic low) to the set logic state (e.g., logic high), the gate driving unit 100 or the driver control circuit 102 may be able to set the switch driving signal DROUT to the driving set logic state (e.g., logic high) immediately once the first detection event has been identified, for instance, at the moments t3, t7 and t11 in the example illustrated in FIG. 2. For such situations, at the moments (e.g., the set moments t3, t7 and t11 in FIG. 2) when the switching device 101 is turned ON, the voltage-drop V_{DS} across the switching device 101 may have substantially decreased to be essentially at zero which may be considered as substantially full ZVS such as for the situations in the switching cycles Tsw (t0˜t4) and Tsw (t8˜t12) illustrated in the example of FIG. 2 or the voltage-drop V_{DS} across the switching device 101 may at least have been largely decreased in comparison with that at the switch-voltage decreasing starting moment (e.g., t6 in FIG. 2) which may be considered as substantially partial ZVS such as for the situation in the switching cycle Tsw (t4˜t8) illustrated in the example of FIG. 2. Therefore, for each switching cycle Tsw, the gate driving unit 100 or the driver control circuit 102 may determine to have identified the situations of substantially full ZVS or substantially partial ZVS if the moment when or at which the gate driving unit 100 or the driver control circuit 102 has identified the first detection event during the first ZVD time window W_{MCZVD} lays back or falls behind the pulse width modulated signal CPWM's changing from the reset logic state (e.g., logic low) to the set logic state (e.g., logic high). For both the situations of substantially full ZVS and substantially partial ZVS, switching loss may be beneficially reduced.

For each switching cycle Tsw, if the moment when or at which the gate driving unit 100 or the driver control circuit 102 has identified the first detection event during the first ZVD time window W_{MCZVD} goes ahead of the moment when the pulse width modulated signal CPWM changes from the reset logic state (e.g., logic low) to the set logic state (e.g., logic high), such as for the situation illustrated in the switching cycle Tsw (t12˜t17) in the example of FIG. 2, the gate driving unit 100 or the driver control circuit 102 may wait until at a time or a moment t16 when the second type transition edge of the pulse width modulated signal CPWM comes to set the switch driving signal DROUT to the driving set logic state (e.g., logic high) after the first detection event has been identified. For such situations, at the moments (e.g., the set moment t16 in FIG. 2) when the switching device 101 is turned ON, the voltage-drop V_{DS} across the switching device 101 may ring and rise up again, which may be considered as substantially non-ZVS.

In accordance with an exemplary embodiment, for each switching cycle Tsw, if the moment (e.g., the moment t15 for the situation illustrated in the switching cycle Tsw (t12˜t17) in FIG. 2) when or at which the gate driving unit 100 or the driver control circuit 102 has identified the first detection event during the first ZVD time window W_{MCZVD} is ahead of the moment (e.g., the moment t16 for the situation illustrated in the switching cycle Tsw (t12˜t17) in FIG. 2) when the second type transition edge of the pulse width modulated signal CPWM comes, the gate driving unit 100 or the driver control circuit 102 may further be configured to detect or check whether the current signal Io (or the miller current I_{MC}) goes to flow in an opposite direction (e.g., flowing into the third terminal 13) which is opposite to the direction in which the current signal Io is flowing during the first ZVD time window W_{MCZVD} (e.g., flowing out of the third terminal 13). For each switching cycle Tsw, if the gate driving unit 100 or the driver control circuit 102 has detected that the current signal Io (or the miller current I_{MC}) is flowing into the third terminal 13 after the first detection event has been identified, the gate driving unit 100 or the driver control circuit 102 may further be configured to determine that a second detection event has been identified, which may be helpful to identify the situation of substantially non-ZVS more accurately. In an embodiment, for each switching cycle Tsw, the gate driving unit 100 or the driver control circuit 102 may be configured to determine that it has identified the second detection event once the current signal Io falls to or below a third predetermined threshold current value Iₜₕ₃ for instance after the first detection event has been identified or after the first ZVD time window W_{MCZVD} expires. The third predetermined threshold current value Iₜₕ₃ may be lower than the second predetermined threshold current value Iₜₕ₂.

In accordance with an exemplary embodiment, for each switching cycle Tsw, the gate driving unit 100 or the driver control circuit 102 may further be configured to enable or set a maximum zero voltage detection (“ZVD”) time period t_{ZVD_WAIT} in response to the moment when the pulse width modulated signal CPWM is changed from the reset logic state (e.g., logic low) to the set logic state (e.g., logic high). The gate driving unit 100 or the driver control circuit 102 may be adapted to be further configured to force setting the switch driving signal DROUT to the driving set logic state (e.g., logic high) if the gate driving unit 100 or the driver control circuit 102 has neither identified the first detection event during the first ZVD time window W_{MCZVD} nor identified the first detection event until the maximum ZVD time period t_{ZVD_WAIT} expires, such as for the situation illustrated in the switching cycle Tsw (t17˜t22) in the example of FIG. 2, the gate driving unit 100 or the driver control circuit 102 forces the switch driving signal DROUT to be set at the driving set logic state (e.g., logic high) at a time or a moment t20 when the maximum ZVD time period t_{ZVD_WAIT} expires while no first detection event (i.e., “MCZVD”) has been detected. For such situation, at the moments (e.g., the set moment t20 in FIG. 2) when the switching device 101 is turned on, the voltage-drop V_{DS} across the switching device 101 may have not been substantially decreased, which may be considered as substantially non-ZVS.

Therefore, in an exemplary embodiment, for each switching cycle Tsw, the gate driving unit 100 or the driver control circuit 102 may determine to have identified a situation of substantially non-ZVS if the moment when or at which the gate driving unit 100 or the driver control circuit 102 has identified the first detection event during the first ZVD time window W_{MCZVD} goes ahead of the second type transition edge of the pulse width modulated signal CPWM, or if the gate driving unit 100 or the driver control circuit 102 has neither identified the first detection event during the first ZVD time window W_{MCZVD} nor identified the first detection event until the maximum ZVD time period t_{ZVD_WAIT} expires. In an alternative exemplary embodiment, for each switching cycle Tsw, the gate driving unit 100 or the driver control circuit 102 may determine to have identified a situation of substantially non-ZVS if the second detection event is identified after the first detection event has been identified or after the first ZVD time window W_{MCZVD} expires, or if the gate driving unit 100 or the driver control circuit 102 has neither identified the first detection event during the first ZVD time window W_{MCZVD} nor identified the first detection event until the maximum ZVD time period t_{ZVD_WAIT} expires.

In accordance with an exemplary embodiment, for each switching cycle Tsw, the gate driving unit 100 or the driver control circuit 102 may further be configured to enable or set the first ZVD time window W_{MCZVD} when a first predetermined leading-edge blanking time t_{MCZVD_LEB} has elapsed since the moment when the switch driving signal DROUT is reset from the driving set logic state (e.g., logic high in the example of FIG. 2) to the driving reset logic state (e.g., logic low in the example of FIG. 2), for instance by providing a first ZVD time window control signal EN_MCZVD as illustratively shown in FIG. 2.

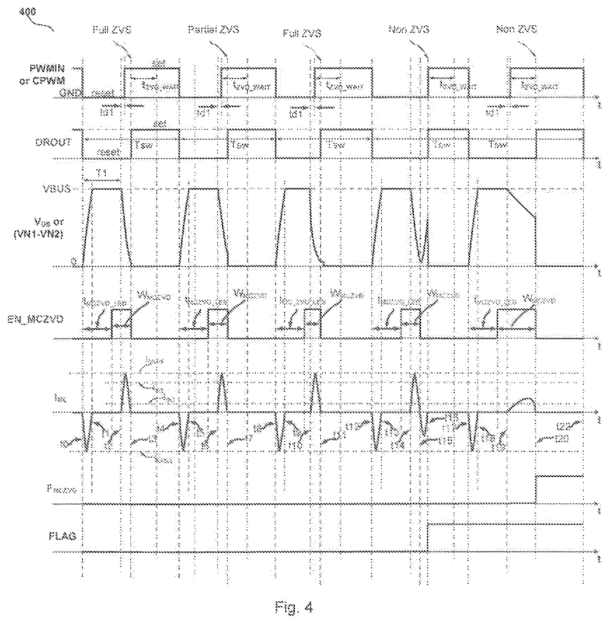

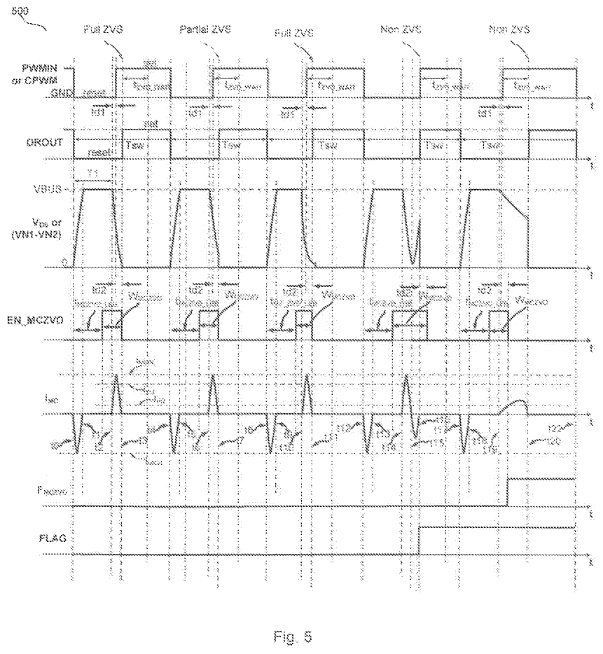

In accordance with an exemplary embodiment, the first window width of the first ZVD time window W_{MCZVD} may be of a first predetermined time duration that may be preset by design according to practical application requirement and application parameters as illustratively shown in FIG. 2. In accordance with an alternative exemplary embodiment, the gate driving unit 100 or the driver control circuit 102 may be configured to adaptively adjust the first window width of the first ZVD time window W_{MCZVD} instead of setting the first window width at the first predetermined time duration. For example, in an embodiment as illustratively shown in FIG. 4, for each switching cycle Tsw, the gate driving unit 100 or the driver control circuit 102 may further be configured to disable or reset the first ZVD time window W_{MCZVD} when the gate driving unit 100 or the driver control circuit 102 has identified the first detection event (or has detected “MCZVD”) or when the switch driving signal DROUT is set from the driving reset logic state (e.g., logic low in the example of FIG. 4) to the set logic (e.g., logic high in the example of FIG. 4), for instance by the first ZVD time window control signal EN_MCZVD as illustratively shown in FIG. 4. For another example, in an alternative embodiment as illustratively shown in FIG. 5, for each switching cycle Tsw, the gate driving unit 100 or the driver control circuit 102 may further be configured to disable or reset the first ZVD time window W_{MCZVD} when a predetermined delay time td2 has elapsed since the moment when the second type transition edge of the pulse width modulated signal CPWM comes, for instance by the first ZVD time window control signal EN_MCZVD as illustratively shown in FIG. 5. One of ordinary skill in the art would understand that there are many other alternative ways to enable or disable the first ZVD time window, which are within the spirit and scope of the present disclosure, except those examples described here.

In accordance with an exemplary embodiment, the gate driving unit 100 or the driver control circuit 102 may further be configured to reset or maintain a first flag signal F_{MCZVD} to a first flag logic state (e.g., logic low in the example of FIG. 2) once the gate driving unit 100 or the driver control circuit 102 has identified the first detection event during the first ZVD time window W_{MCZVD}. The gate driving unit 100 or the driver control circuit 102 may further be configured to set or keep the first flag signal F_{MCZVD} at a second flag logic state (e.g., logic high in the example of FIG. 2) if it has not identified the first detection event during the first ZVD time window W_{MCZVD}.

In accordance with an exemplary embodiment, the gate driving unit 100 or the driver control circuit 102 may further be configured to provide a ZVS indication signal FLAG, and to reset or maintain the ZVS indication signal FLAG at a first indication logic state (e.g., logic low in the example of FIG. 2) once the gate driving unit 100 or the driver control circuit 102 has identified a situation of substantially full ZVS or substantially partial ZVS while setting or maintaining the ZVS indication signal FLAG at a second indication logic state (e.g., logic high in the example of FIG. 2) if the gate driving unit 100 or the driver control circuit 102 has identified a situation of substantially non-ZVS.

In accordance with an exemplary embodiment, the gate driving unit 100 may further have a fourth terminal 14 that may be adapted to be configured as a first power supply terminal of the gate driving unit 100. The fourth terminal 14 may be adapted to be configured to provide a first supply voltage VDD. The first supply voltage VDD may be used to supply power for circuitries such as the driver control circuit 102 and the driver 103 etc. of the gate driving unit 100. A first capacitive device C1 may be coupled to the fourth terminal 14 in practical application. In an exemplary embodiment, the first capacitive device C1 and a second capacitive device C2 may be coupled in series between the fourth terminal 14 and the second terminal 12, and a common connection N3 of the first capacitive device C1 and the second capacitive device C2 may be coupled to the second power node N2.

In accordance with an exemplary embodiment, gate driving unit 100 may further include a first fault detection and/or fault protection circuit 141. For instance, in an embodiment, the first fault detection and/or fault protection circuit 141 may include a first under voltage protection circuit UVLO1 and may be configured to detect whether the first supply voltage VDD is below a first under voltage threshold V_{UV1}. In an embodiment, if the first supply voltage VDD is below the first under voltage threshold V_{UV1}, the first under voltage protection circuit UVLO1 may control the switch driving signal DROUT to be locked at the driving reset logic state (e.g., logic low) for instance by an internal active-low clamp circuitry which may be included in the driver control circuit 102.

In accordance with an exemplary embodiment, the gate driving unit 100 may further comprise an isolation circuit 104 that may be adapted to be configured to provide a galvanic isolation between a primary side and a secondary side of the gate driving unit 100. The gate driving unit 100 may include a primary control circuit 105 at the primary side. The driver control circuit 102 and the driver 103 may be disposed at the secondary side. The gate driving unit 100 may further include a fifth terminal 15 that may be adapted to be configured as a primary control terminal IN, a sixth terminal 16 that may be adapted to be configured as a primary side reference ground terminal GND for circuitries at the primary side of the gate driving unit 100, and a seventh terminal 17 that may be adapted to be configured as a primary side power supply terminal of the gate driving unit 100. The seventh terminal 17 may be adapted to be configured to provide a second supply voltage VCC for circuitries at the primary side such as the primary control circuit 105 etc. A third capacitive device C3 may be coupled to the seventh terminal 17 in practical application. For this situation, the second terminal 12 and the fourth terminal 14 may respectively function as a secondary side reference ground terminal and a secondary side power supply terminal of the gate driving unit 100 to respectively provide a reference ground potential VEE and the first supply voltage VDD for circuitries (such as the driver control circuit 102 and the driver 103 etc.) at the secondary side of the gate driving unit 100. With such configuration, the gate driving unit 100 may be suitable to be used in power conversion applications that can handle high power or high voltage. One of ordinary skill in the art should understand that this is just to provide an example, the isolation circuit 104, the circuitries at the primary side (such as the primary control circuit 105 etc.) and the associated terminals at the primary side (such as the fifth terminal 15, the sixth terminal 16 and the seventh terminal 17 etc.) may be optional or unnecessary components for low power or low voltage applications.

In accordance with an exemplary embodiment, the fifth terminal 15 may be configured to receive a gate control signal PWMIN. The gate control signal PWMIN may include a logic signal having a logic state switching between a reset logic state (e.g., logic low) and a set logic state (e.g., logic high) with a switching frequency. The gate driving unit 100 may be configured to transmit the gate control signal PWMIN to the secondary side for instance through a first signal isolation and transmission channel CH1 in the isolation circuit 104 and the control terminal or control node 11 may receive the signal transmitted to the secondary side as the pulse width modulated signal CPWM. In an embodiment, before being transmitted through the first signal isolation and transmission channel CH1, the gate control signal PWMIN may be signal processed by the primary control circuit 105, for instance as illustrated in the example of FIG. 1. However, in an alternative embodiment, the gate control signal PWMIN may not need to be signal processed by the primary control circuit 105 before being transmitted through the first signal isolation and transmission channel CH1. One of ordinary skill in the art would understand that for embodiments where the isolation circuit 104 and the circuitries at the primary side are omitted, the gate control signal PWMIN may be directly provided to, for instance, the third terminal 13 and used as the pulse width modulated signal CPWM.

In accordance with an exemplary embodiment, the primary control circuit 105 may include a primary fault detection and/or fault protection circuit 1051. For instance, in an embodiment, the primary fault detection and/or fault protection circuit 1051 may include a second under voltage protection circuit UVLO2 and may be configured to detect whether the second supply voltage VCC is below a second under voltage threshold V_{UV2}. In an embodiment, if the second supply voltage VCC is below the second under voltage threshold V_{UV2}, the second under voltage protection circuit UVLO2 may force the switch driving signal DROUT to be locked at the driving reset logic state (e.g., logic low) for instance by an internal active-low clamp circuitry which may be included in the driver control circuit 102.

In accordance with an exemplary embodiment, the primary control circuit 105 may further include a primary control signal processing circuit 1052, for instance, in an embodiment, the primary control signal processing circuit 1052 shown in FIG. 1 as an example.

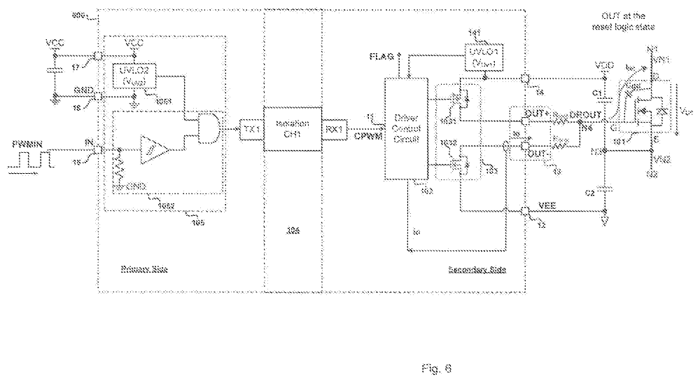

In accordance with an exemplary embodiment, the third terminal 13 (e.g., the output terminal) of the gate driving unit 100 may include a non-inverting output terminal OUT+ and an inverting output terminal OUT−. FIG. 6 illustrates an exemplary schematic diagram of a gate driving unit 600 which may be considered as an exemplary embodiment of the gate driving unit 100 with the third terminal 13 comprising the non-inverting output terminal OUT+ and the inverting output terminal OUT− in accordance with an exemplary embodiment of the present disclosure. The non-inverting output terminal OUT+ may be adapted to be coupled to a common driving connection node N4 for instance with or without a first resistive device R_{SRC}. The inverting output terminal OUT− may be adapted to be coupled to the common driving connection node N4 for instance with or without a second resistive device R_{SNK}. The common driving connection node N4 may be coupled to the control terminal G of the switching device 101 when the gate driving unit 100 is used for practical application configurations. For this exemplary embodiment, the feedback signal indicative of the current signal Io flowing through the third terminal 13 may be detected or monitored on the inverting output terminal OUT−. In an exemplary embodiment, the non-inverting output terminal OUT+ may be adapted to be configured to set the switch driving signal DROUT at the driving set logic state (e.g., logic high) to drive the switching device 101 ON when a signal of logic high is asserted at this non-inverting output terminal OUT+. The non-inverting output terminal OUT+ may be adapted to be configured to have a high impedance state (e.g., high-z) when the switch driving signal DROUT needs to be reset at the driving reset logic state (e.g., logic low). The inverting output terminal OUT− may be adapted to be configured to reset the switch driving signal DROUT at the driving reset logic state (e.g., logic low) to drive the switching device 101 OFF when a signal of logic low is asserted at this inverting output terminal OUT−. The inverting output terminal OUT− may be adapted to be configured to have a high impedance state (e.g., high-z) when the switch driving signal DROUT needs to be set at the driving set logic state (e.g., logic high).

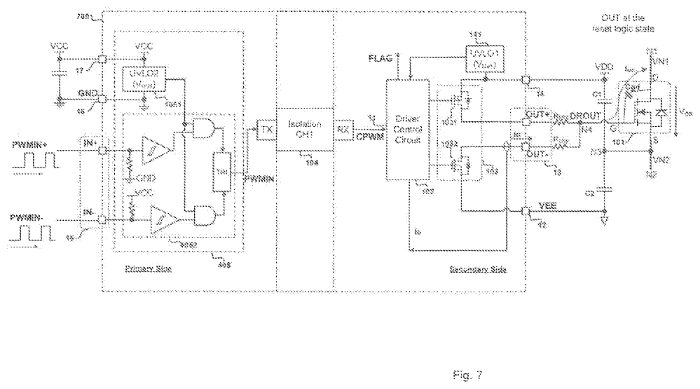

In accordance with an exemplary embodiment, the fifth terminal 15 (e.g., the primary control terminal IN) of the gate driving unit 100 may include a non-inverting input terminal IN+ and an inverting input terminal IN−. FIG. 7 illustrates an exemplary schematic diagram of a gate driving unit 700 which may be considered as an exemplary embodiment of the gate driving unit 100 with the fifth terminal 15 comprising the non-inverting input terminal IN+ and the inverting input terminal IN− in accordance with an exemplary embodiment of the present disclosure. The non-inverting input terminal IN+ may be adapted to be configured to receive for instance a first gate control signal PWMIN+. The inverting input terminal IN− may be adapted to be configured to receive for instance a second gate control signal PWMIN−. For this situation, the first gate control signal PWMIN+ and the second gate control signal PWMIN− define or determine the gate control signal PWMIN. In an exemplary embodiment, the non-inverting input terminal IN+ may be internally pulled at the reset logic state (e.g., logic low) while the inverting input terminal IN− may be internally pulled at the set logic state (e.g., logic high). The term “internally” here may refer to inside the gate driving unit 100. In an exemplary embodiment, the gate control signal PWMIN or the pulse width modulated signal CPWM may be at the set logic state (e.g., logic high) when the first gate control signal PWMIN+ is at the set logic state (e.g., logic high) and the second gate control signal PWMIN− is at the reset logic state (e.g., logic low), else the gate control signal PWMIN or the pulse width modulated signal CPWM may be at the reset logic state (e.g., logic low). In an embodiment, the gate driving unit 100 may be configured to further provide inverting input and non-inverting input overlap protection (also referred to as IN+/IN− overlap protection) which keeps the switch driving signal DROUT at the reset logic state as long as the second gate control signal PWMIN− is at the set logic state (e.g., logic high).

For this example, the gate driving unit 700 may include a primary control circuit 405 which may be considered as a variant from the primary control circuit 105. In an exemplary embodiment, the primary control circuit 405 may include the primary fault detection and/or fault protection circuit 1051. The primary control circuit 405 may further include a primary control signal processing circuit 4052, for instance, in an embodiment, the primary control signal processing circuit 4052 shown in FIG. 7 as an example. In an embodiment, the primary control signal processing circuit 4052 may set an internal time delay tdd so that the set logic state (e.g., logic high) of the first gate driving signal PWMIN+ and the set logic state (e.g., logic high) of the second gate control signal PWMIN− do not overlap.

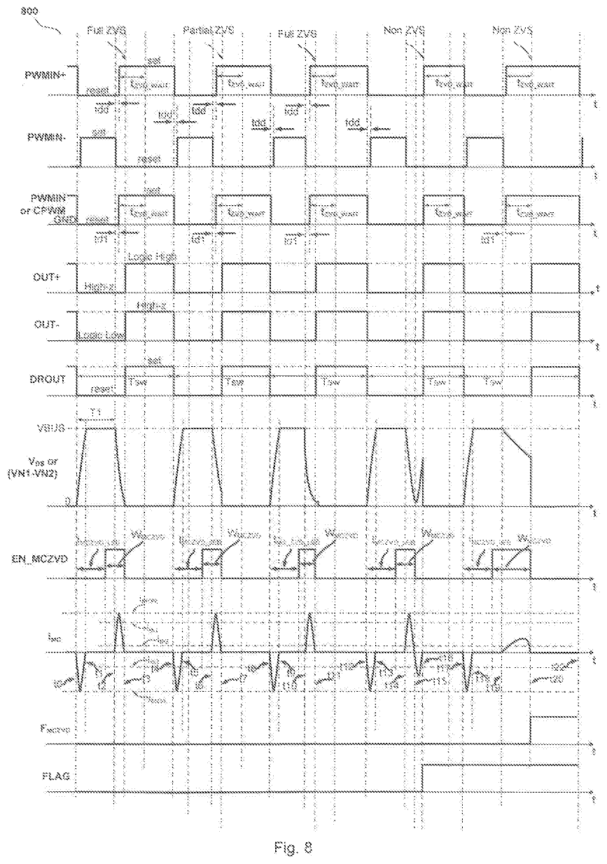

FIG. 8 illustrates a waveform diagram 800 showing waveforms of several signals of the gate driving unit 700 with the third terminal 13 split into OUT+ and OUT− and the fifth terminal 15 split into IN+ and IN− in accordance with an exemplary embodiment of the present invention.

In accordance with an exemplary embodiment, the gate driving unit 100 may further include a reporting terminal 18. The reporting terminal 18 may be adapted to be configured to provide a reporting signal RPT according to various operation status of the gate driving unit 100. The gate driving unit 100 may further be configured to adjust the reporting signal RPT based on the current signal Io. In an embodiment, for instance, the gate driving unit 100 may be configured to set the reporting signal RPT to a first report status during normal operation. The gate driving unit 100 may be considered as in normal operation when the substantially non-ZVS situations have not been identified and/or fault events such as a short circuit event have not been detected.

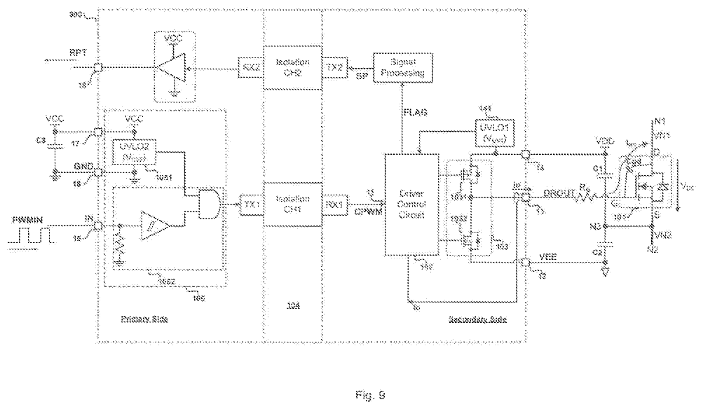

FIG. 9 schematically illustrates a gate driving unit 900 in accordance with an embodiment of the present invention. Components or structures or elements in the gate driving unit 900 with substantially the same/similar functions as those of the gate driving unit 100 are identified by the same reference labels as used in the gate driving unit 100 for the sake of simplicity. One of ordinary skill in the art would understand that the gate driving unit 900 may be considered as a variant from the gate driving unit 100 or may be deemed as an exemplary embodiment of the gate driving unit 100 further having the reporting terminal 18. Therefore, the above descriptions to the gate driving unit 100 and the driver control circuit 102 of the various embodiments of the present disclosure made with reference to FIG. 1 to FIG. 8 are applicable to the gate driving unit 900.

In an exemplary embodiment, the gate driving unit 900 may further be configured to report a ZVS status to the reporting terminal 18 for instance by providing the ZVS indication signal FLAG to the reporting terminal 18 as the reporting signal RPT. In an alternative exemplary embodiment, the gate driving unit 900 may be configured to let the reporting signal RPT to have the first report status during normal operation, and may further be configured to set the reporting signal RPT to a second report status according to the ZVS indication signal FLAG when the gate driving unit 900 has identified the situations of substantially non-ZVS. The second report status is different from the first report status. Here in the example of FIG. 9, the gate driving unit 900 may be considered as in normal operation when substantially non-ZVS situations have not been identified. In an embodiment, the first report status may be embodied as a logic low signal and the second report status may be embodied as a logic high signal. For another instance, the first report status may include or be embodied as a pulse signal and the second report status may include or embodied as a logic high signal or a logic low signal. Or in still yet another embodiment, the first report status may include or be embodied as a first pulse signal of a first frequency while the second report status may include or be embodied as a second pulse signal of a second frequency different from the first frequency. One of ordinary skill in the art would understand that there are many other alternative ways to set the first report status and the second report status that may not be exhaustively listed out here. In an embodiment, the gate driving unit 900 may further include a signal processing circuit to provide a signal SP for setting the reporting signal RPT to the first report status or to the second report status at least partially based on the ZVS indication signal FLAG.

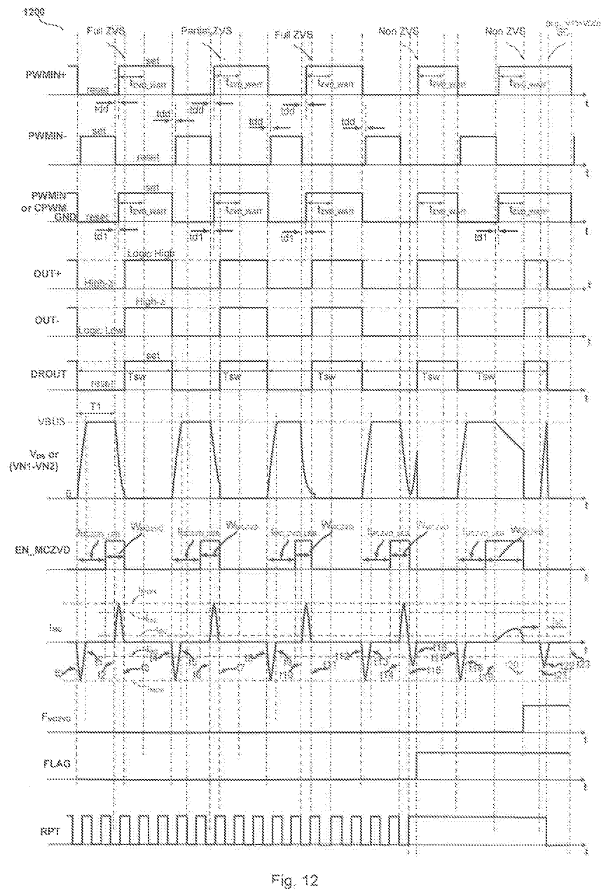

Referring to the exemplary illustration in FIG. 12, it is exemplarily shown that the first report status may include or be embodied as a pulse signal and the second report status may include or be embodied as a logic high signal. It may be understood that FIG. 12 illustrates a waveform diagram 1200 showing waveforms of several signals of a gate driving unit having the reporting terminal 18 in accordance with an exemplary embodiment of the present invention.

In an exemplary embodiment, the reporting terminal 18 may be disposed at the primary side of the gate driving unit 900 for embodiments having the isolation circuit 104 provided in the gate driving unit 900 that may be suitable to be used in power conversion applications that can handle high power or high voltage. For this situation, the isolation circuit 104 in the gate driving unit 900 may further include a second isolation and transmission channel CH2. The driver control circuit 102 may be coupled to the isolation circuit 104 to report the ZVS status to the reporting terminal 18 through the second isolation and transmission channel CH2, for instance by transmitting the ZVS indication signal FLAG to the primary side of the gate driving unit 900 via the second isolation and transmission channel CH2, or by transmitting the signal SP to the primary side via the second isolation and transmission channel CH2 to set the reporting signal RPT to the first report status or to the second report status for another instance.

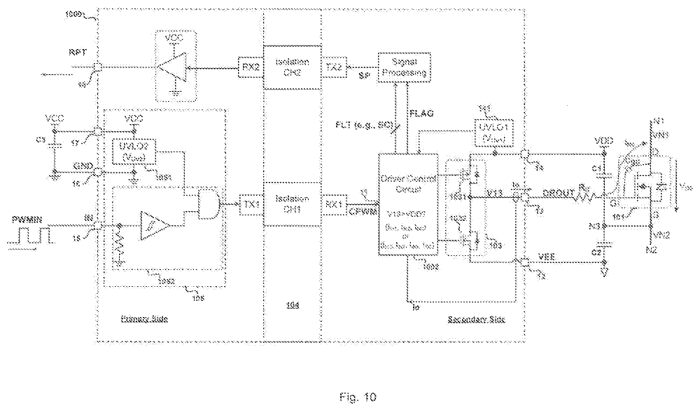

FIG. 10 schematically illustrates a gate driving unit 1000 in accordance with an embodiment of the present invention. Components or structures or elements in the gate driving unit 1000 with substantially the same/similar functions as those of the gate driving unit 100 are identified by the same reference labels as used in the gate driving unit 100 for the sake of simplicity. One of ordinary skill in the art would understand that the gate driving unit 1000 may be considered as a variant from the gate driving unit 100. The gate driving unit 1000 may include a driver control circuit 1002 that may be considered as a variant from the driver control circuit 102. Therefore, the above descriptions to the gate driving unit 100 and the driver control circuit 102 of the various embodiments of the present disclosure made with reference to FIG. 1 to FIG. 9 are applicable respectively to the gate driving unit 1000 and the driver control circuit 1002. In comparison with the gate driving unit 100, the gate driving unit 1000 in one aspect may further be adapted to be configured to implement short circuit detection.

In accordance with an exemplary embodiment, the gate driving unit 1000 or the driver control circuit 1002 of the gate driving unit 1000 may further be adapted to be configured to monitor or detect whether a short circuit event SC is occurring (e.g., short circuit on the third terminal 13 or on the switching device 101 etc.) based on the feedback signal indicative of the current signal Io flowing through the third terminal 13 when the gate driving unit 1000 is used for practical application configurations to drive the switching device 101. In an embodiment, when the switch driving signal DROUT is at the driving set logic state (e.g., logic high), the gate driving unit 1000 or the driver control circuit 1002 may further be configured to detect a direction of the current signal Io and determine that the short circuit event SC is occurring (or alternatively being referred to as the short circuit event SC is detected) once it has detected that the current signal Io is flowing into the third terminal 13 and the phenomenon of the current signal Io flowing into the third terminal 13 persists (or lasts) for a predetermined short circuit detection time t_{SC}. For this situation, the current signal Io may include the miller current I_{MC} flowing through the control terminal G of the switching device 101. For instance, please refer to the situation illustratively shown in the switching cycle Tsw (t17˜t22) in FIG. 12 as an example. At a time or a moment t21, the gate driving unit 1000 or the driver control circuit 1002 may identify that the current signal Io (or the miller current I_{MC}) is flowing into the third terminal 13 and at the moment t22 the phenomenon of the current signal Io flowing into the third terminal 13 persists (or lasts) for a predetermined short circuit detection time t_{SC} may be identified, and thus the gate driving unit 1000 or the driver control circuit 1002 may determine that the short circuit event SC is occurring (or the short circuit event SC is detected) at the moment t22 in the example shown in FIG. 12.

In accordance with an exemplary embodiment, when the switch driving signal DROUT is at the driving set logic state (e.g., logic high), the gate driving unit 1000 or the driver control circuit 1002 of the gate driving unit 1000 may be configured to detect the direction of the current signal Io by monitoring or detecting whether a voltage V13 on the third terminal 13 goes higher than the first supply voltage VDD. In an example, if the voltage V13 on the third terminal 13 becomes higher than the first supply voltage VDD, the gate driving unit 1000 or the driver control circuit 1002 may be configured to determine that it has detected the current signal Io is flowing into the third terminal 13 or the short circuit event SC is detected. In an alternative example, the gate driving unit 1000 or the driver control circuit 1002 may be configured to determine that the short circuit event SC is detected if the voltage V13 on the third terminal 13 becomes higher than the first supply voltage VDD (for instance also illustrated as at the moment t22) and does not fall below a voltage value of the first supply voltage minus a predetermined hysteresis voltage value.

In an exemplary embodiment, the gate driving unit 1000 or the driver control circuit 1002 may further be configured to reset the switch driving signal DROUT to the driving reset logic state (e.g., logic low) when the short circuit event SC is detected to turn the switching device 101 OFF. For instance, referring to the illustration in the example shown in FIG. 12, the switching driving signal DROUT is reset to the driving reset logic state (e.g., logic low) at the moment t22 when the short circuit event SC is detected, earlier than a time or a moment t23 when the pulse width modulated signal CPWM is changed from the set logic state (e.g., logic high) to the reset logic state (e.g., logic low) for this situation.

In an exemplary embodiment, the gate driving unit 1000 or the driver control circuit 1002 may further be configured to provide a fault indication signal FLT indicative of a fault event for instance including the short circuit event SC.

In an exemplary embodiment, the gate driving unit 1000 may be configured to let the reporting signal RPT to have the first report status during normal operation, and may further be configured to set the reporting signal RPT to the second report status according to the ZVS indication signal FLAG when the gate driving unit 1000 has identified the situations of substantially non-ZVS, and may further be configured to set the reporting signal RPT to a third report status according to the fault indication signal FLT when the fault event such as the short circuit event SC is detected. Here in the example of FIG. 10, the gate driving unit 1000 may be considered as in normal operation when substantially non-ZVS situations have not been identified and fault events such as the short circuit event have not been detected. The first report status, the second report status and the third report status are different from each other. For instance, in an embodiment, the first report status may include or be embodied as a logic low signal, the second report status may include or be embodied as a logic high signal, and the third report status may include or be embodied as a signal having an amplitude different from the logic low signal and the logic high signal. For another instance, the first report status may include or be embodied as a pulse signal, the second report status may include or embodied as a logic high signal (or a logic low signal) and the third report status may include or be embodied as a logic low signal (or a logic high signal), as illustrated in the example of FIG. 12. Or in still yet another embodiment, the first report status may include or be embodied as a first pulse signal of a first frequency, the second report status may include or embodied as a second pulse signal of a second frequency different from the first frequency, and the third report status may include or be embodied as a third pulse signal of a third frequency different from the first frequency and the second frequency. One of ordinary skill in the art would understand that there are many other alternative ways to set the first report status and the second report status that may not be exhaustively listed out here. In an embodiment, similar as the gate driving unit 900, the gate driving unit 1000 may include a signal processing circuit to provide a signal SP for setting the reporting signal RPT to the first report status or to the second report status or to the third report status at least partially based on the ZVS indication signal FLAG and the fault indication signal FLT.

In an exemplary embodiment, the reporting terminal 18 may be disposed at the primary side of the gate driving unit 1000 for embodiments having the isolation circuit 104 provided in the gate driving unit 1000 that may be suitable to be used in high power or high voltage power conversion applications. For this situation, the isolation circuit 104 in the gate driving unit 1000 may further include the second isolation and transmission channel CH2. The gate driving unit 1000 may transmit the signal SP to the primary side via the second isolation and transmission channel CH2 to set the reporting signal RPT to the first report status or to the second report status or to the third report status.

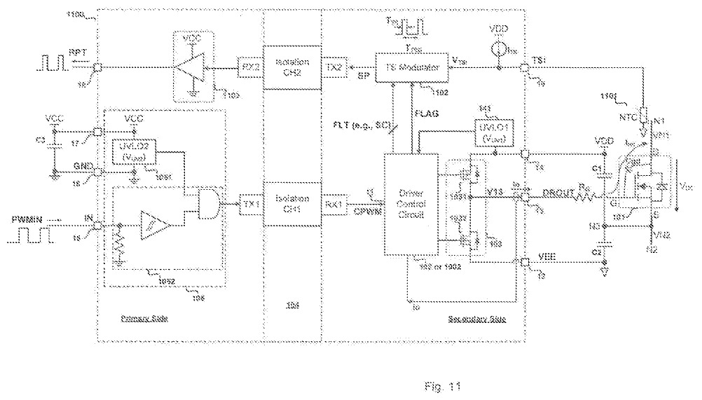

FIG. 11 schematically illustrates a gate driving unit 1100 in accordance with an embodiment of the present invention. Components or structures or elements in the gate driving unit 1100 with substantially the same/similar functions as those of the gate driving unit 100 or the gate driving unit 1000 are identified by the same reference labels as used in the gate driving unit 100 or gate driving unit 1000 for the sake of simplicity. One of ordinary skill in the art would understand that the gate driving unit 1100 may be considered as a variant from the gate driving unit 100 or the gate driving unit 1100. Therefore, the above descriptions to the gate driving unit 100 or the gate driving unit 1000 of the various embodiments of the present disclosure made with reference to FIG. 1 to FIG. 10 are applicable to the gate driving unit 1100 in FIG. 11. In comparison with the gate driving unit 100 or the gate driving unit 1000, the gate driving unit 1100 in one aspect may further be adapted to be configured to implement temperature sensing.

In accordance with an exemplary embodiment, the gate driving unit 1100 may further include a temperature sensing input (“TSI”) terminal 19. The TSI terminal 19 may be adapted to be configured to detect a temperature reading signal indicative of a temperature of the switching device 101. In an embodiment, a temperature sensor 1101 such as an NTC thermistor or temperature sensing diode may be coupled between the TSI terminal 19 and the second terminal 12 during practical application. The TSI terminal 19 may be configured to source a temperature sensing current I_{TS} to the temperature sensor 1101 and detect a temperature sensing voltage V_{TSI} across the temperature sensor 1101 as the temperature reading signal. The gate driving unit 1100 may further be configured to provide a temperature report signal TSO to the reporting terminal 18. The temperature report signal TSO may include a pulse width modulated signal having a pulse width (or a pulse duration) T_{TS} or a duty cycle D_{TS} indicative of the sensed temperature. The duty cycle D_{TS} may refer to a ratio of the pulse width T_{TS} to a switching period T_{TSO} in each switching cycle of the temperature report signal TSO, i.e., D_{TS}=T_{TS}/T_{TSO}.

In accordance with an exemplary embodiment, similar as the gate driving unit 900 or 1000, the gate driving unit 1100 may further include a signal processing circuit, such as a temperature sensing modulator (also referred to as TS modulator) 1102 adapted to be configured to generate the temperature report signal TSO based on the temperature reading signal, for instance the temperature sensing voltage V_{TSI} across the temperature sensor 1101 in the example shown in FIG. 11.

In accordance with an exemplary embodiment, similar as the gate driving unit 1000, the gate driving unit 1100 may be configured to let the reporting signal RPT have a first report status during normal operation (e.g., no substantially non-ZVS situations have been identified and no fault events such as short circuit event has been detected), wherein the first report status includes or is embodied as the temperature report signal TSO in this particular example. The gate driving unit 1100 may further be configured to set the reporting signal RPT to a second report status (e.g., embodied as a logic high signal in an embodiment) according to the ZVS indication signal FLAG when the gate driving unit 1100 has identified the situations of substantially non-ZVS. The gate driving unit 1100 may further be configured to set the reporting signal RPT to a third report status (e.g., embodied as a logic low signal in an embodiment) according to the fault indication signal FLT when fault events such as the short circuit event SC are detected. One of ordinary skill in the art could still refer to the illustration in the example of FIG. 12 for understanding. In an embodiment, the signal processing circuit (or the TS modulator) 1102 may further be configured to provide a signal SP for setting the reporting signal RPT to the first report status or to the second report status or to the third report status at least partially based on the temperature report signal TSO, the ZVS indication signal FLAG and the fault indication signal FLT.

In an exemplary embodiment, the reporting terminal 18 may be disposed at the primary side of the gate driving unit 1100 for embodiments having the isolation circuit 104 provided in the gate driving unit 1000 that may be suitable to be used in power conversion applications that can handle high power or high voltage. The TSI terminal 19 and the signal processing circuit may be disposed at the secondary side of the gate driving unit 1100. For this situation, the isolation circuit 104 in the gate driving unit 1100 may further include the second isolation and transmission channel CH2. The gate driving unit 1100 may transmit the signal SP to the primary side via the second isolation and transmission channel CH2 to set the reporting signal RPT to the first report status or to the second report status or to the third report status.

The advantages of the various embodiments of the present invention are not confined to those described above. These and other advantages of the various embodiments of the present invention will become more apparent upon reading the whole detailed descriptions and studying the various figures of the drawings.

From the foregoing, it will be appreciated that specific embodiments of the present invention have been described herein for purposes of illustration, but that various modifications may be made without deviating from the technology. Many of the elements of one embodiment may be combined with other embodiments in addition to or in lieu of the elements of the other embodiments. Accordingly, the present invention is not limited except as by the appended claims.

What is claimed is:

1. A gate driving unit comprising:
a first terminal adapted to be configured as a control terminal to receive a pulse width modulated signal having a set logic state and a reset logic state;
a second terminal adapted to be configured as a reference ground terminal; and
a third terminal adapted to be configured as an output terminal of the gate driving unit for providing a switch driving signal having a logic state including a driving set logic state and a driving reset logic state; wherein
the gate driving unit is configured to detect or monitor a current signal flowing through the third terminal, and further configured to control the logic state of the switch driving signal based on the pulse width modulated signal and the current signal.

2. The gate driving unit of claim 1, wherein the gate driving unit is further configured to reset the switch driving signal at the driving reset logic state in response to the pulse width modulated signal's changing from the set logic state to the reset logic state.

3. The gate driving unit of claim 1, wherein the gate driving unit is further configured to determine whether a first detection event has been identified during a first detection time window based on the current signal, and wherein the first detection time window has a first window width and is enabled during the switch driving signal is at the driving reset logic state.

4. The gate driving unit of claim 3, wherein the gate driving unit is further configured to set the switch driving signal at the driving set logic state on condition that the first detection event has been identified during the first detection time window and the pulse width modulated signal is at the set logic state.

5. The gate driving unit of claim 3, wherein the gate driving unit is further configured to determine that the first detection event has been identified during the first detection time window if the current signal rises to or above a first predetermined threshold current value and then falls back to or below a second predetermined threshold current value during the first detection time window.

6. The gate driving unit of claim 3, wherein the gate driving unit is further configured to enable or set the first detection time window when a first predetermined leading-edge blanking time has elapsed since a moment when the switch driving signal is reset from the driving set logic state to the driving reset logic state.

7. The gate driving unit of claim 3, wherein:
the gate driving unit is further configured to enable a maximum detection time period in response to the pulse width modulated signal's changing from the reset logic state to the set logic state, and to force the switch driving signal to be set at the driving set logic state if the first detection event has not been identified until the maximum detection time period expires.

8. The gate driving unit of claim 3, wherein:
the gate driving unit is further configured to enable a maximum detection time period in response to the pulse width modulated signal's changing from the reset logic state to the set logic state; and wherein
the gate driving unit is further configured to determine that a situation of substantially non-ZVS is identified if a moment when the first detection event has been identified is ahead of a moment when the pulse width modulated signal is changed from the reset logic state to the set logic state during a switching cycle of the switch driving signal, or if a second detection event of the current signal falling to or below a third predetermined threshold current value is identified after the first detection event has been identified during the switching cycle of the switch driving signal, or if the first detection event has not been identified until the maximum detection time period expires.

9. The gate driving unit of claim 1, further comprising:
a reporting terminal, configured to provide a reporting signal.

10. The gate driving unit of claim 9, wherein the gate driving unit is further configured to set the reporting signal to a first report status during normal operation.

11. The gate driving unit of claim 10, wherein the gate driving unit is further configured to set the reporting signal to a second report status when a situation of substantially non-ZVS is identified.

12. The gate driving unit of claim 10, wherein the gate driving unit is further configured to set the reporting signal to a third report status when a short circuit event is detected.

13. The gate driving unit of claim 10, wherein the gate driving unit is further configured to set the reporting signal to a second report status when a situation of substantially non-ZVS is identified and to set the reporting signal to a third report status when a short circuit event is detected, and wherein the first report status, the second report status and the third report status are different from each other.

14. The gate driving unit of claim 11, wherein:
the gate driving unit is further configured to determine that the situation of substantially non-ZVS is identified if a moment when the gate driving unit has identified the first detection event is ahead of a moment when the pulse width modulated signal is changed from the reset logic state to the set logic state during a switching cycle of the switch driving signal, or
if a second detection event of the current signal falling to or below a third predetermined threshold current value is identified after the first detection event has been identified during the switching cycle of the switch driving signal, or
if the first detection event has not been identified until a maximum detection time period expires since a moment when the pulse width modulated signal is changed from the reset logic state to the set logic state.

15. The gate driving unit of claim 12, wherein the gate driving unit is further configured to determine that the short circuit event is detected if the current signal is flowing into the third terminal for a predetermined short circuit detection time during the switch driving signal is at the driving set logic state or if a voltage on the third terminal is higher than a first supply voltage on a fourth terminal of the gate driving unit during the switch driving signal is at the driving set logic state.

16. The gate driving unit of claim 10, further comprising:
a temperature sensing input terminal, adapted to be configured to detect a temperature reading signal; and wherein
the gate driving unit is further configured to provide a temperature report signal having a pulse width modulated by the temperature reading signal; and wherein
the gate driving unit is further configured to set the reporting signal to a first report status embodied as the temperature report signal during normal operation.

17. The gate driving unit of claim 16,
wherein the gate driving unit is further configured to set the reporting signal to a second report status when the gate driving unit has identified a situation of substantially non-ZVS, the second report status being different from the first report status.

18. The gate driving unit of claim 16, wherein the gate driving unit is further configured to set the reporting signal to a third report status when a short circuit event is detected.

19. The gate driving unit of claim 16,
wherein the gate driving unit is further configured to set the reporting signal to a second report status when the gate driving unit has identified a situation of substantially non-ZVS and to set the reporting signal to a third report status when the gate driving unit has detected a short circuit event, and wherein the first report status, the second report status and the third report status are different from each other.

20. The gate driving unit of claim 1, wherein when the switch driving signal is at the driving set logic state, the gate driving unit is further configured to determine that a short circuit event is detected if the current signal is flowing into the third terminal for a predetermined short circuit detection time or if a voltage on the third terminal is higher than a first supply voltage on a fourth terminal of the gate driving unit.

21. The gate driving unit of claim 20, wherein the gate driving unit is further configured to reset the switch driving signal to the driving reset logic state when the short circuit event is detected.

22. The gate driving unit of claim 1, wherein
the third terminal of the gate driving unit includes a non-inverting output terminal and an inverting output terminal; and wherein
the non-inverting output terminal is adapted to be coupled to a common driving connection node with or without a first resistive device, and the inverting output terminal is adapted to be coupled to the common driving connection node with or without a second resistive device; and wherein
the common driving connection node is configured to provide the switch driving signal; and wherein
the current signal flowing through the third terminal is detected or monitored on the inverting output terminal.

23. The gate driving unit of claim 22, wherein
the non-inverting output terminal is configured to set the switch driving signal at the driving set logic state when a signal of logic high is asserted at this non-inverting output terminal and is further configured to have a high impedance state when the switch driving signal is reset at the driving reset logic state; and wherein
the inverting output terminal is configured to reset the switch driving signal at the driving reset logic state when a signal of logic low is asserted at this inverting output terminal and is further configured to have a high impedance state when the switch driving signal is set at the driving set logic state.

24. The gate driving unit of claim 1, further comprising:
a fourth terminal, configured as a first power supply terminal of the gate driving unit adapted to be configured to provide a first supply voltage.

25. The gate driving unit of claim 1, further comprising:
an isolation circuit, adapted to be configured to provide a galvanic isolation between a primary side and a secondary side of the gate driving unit; and
a fifth terminal, disposed at the primary side and adapted to be configured to receive a gate control signal; and wherein
the first terminal, the second terminal and the third terminal are disposed at the secondary side; and wherein
the isolation circuit includes a first signal isolation and transmission channel adapted to be configured to couple the fifth terminal to the first terminal so that the gate control signal can be transmitted to the secondary side as the pulse width modulated signal.

26. The gate driving unit of claim 25, further comprising:
a sixth terminal, disposed at the primary side and adapted to be configured as a primary side reference ground terminal for circuitries at the primary side of the gate driving unit; and
a seventh terminal, disposed at the primary side and adapted to be configured as a primary side power supply terminal of the gate driving unit.

27. The gate driving unit of claim 25, wherein the fifth terminal includes a non-inverting input terminal and an inverting input terminal, and wherein the non-inverting input terminal is adapted to be configured to receive a first gate control signal, and the inverting input terminal is adapted to be configured to receive a second gate control signal; and wherein the first gate control signal and the second gate control signal determine the gate control signal.

28. The gate driving unit of claim 27, wherein the isolation circuit is omitted and the gate control signal is provided as the pulse width modulated signal.

29. The gate driving unit of claim 25, further comprising:
a reporting terminal, disposed at the primary side and configured to provide a reporting signal.

30. The gate driving unit of claim 29, further comprising:
a temperature sensing input terminal, disposed at the secondary side and adapted to be configured to detect a temperature reading signal; and wherein
the gate driving unit is further configured to provide a temperature report signal having a pulse width modulated by the temperature reading signal; and wherein
the gate driving unit is further configured to set the reporting signal to a first report status embodied as the temperature report signal during normal operation.

31. The gate driving unit of claim 1, wherein the third terminal is coupled to a control terminal of a switching device, and wherein the current signal includes a miller current flowing through the control terminal of the switching device and indicative of a changing rate of a voltage-drop across the switching device.

32. A gate driving unit comprising:
a first terminal adapted to be configured as a control terminal;
a second terminal adapted to be configured as a reference ground terminal;
a third terminal adapted to be configured as an output terminal of the gate driving unit; and
a fourth terminal adapted to be configured as a power supply terminal of the gate driving unit; wherein
the gate driving unit is configured to provide a switch driving signal having a logic state including a driving set logic state and a driving reset logic state at the third terminal, and further configured to identify an operation status of the gate driving unit based on a current signal flowing through the third terminal.

33. The gate driving unit of claim 32, wherein the gate driving unit is further configured to control the logic state of the switch driving signal based on a pulse width modulated signal received at the first terminal and the current signal.

34. The gate driving unit of claim 32, further comprising:
a reporting terminal, configured to provide a reporting signal indicative of the operation status.

35. A gate driving unit comprising:
a first terminal adapted to be configured as a control terminal to receive a pulse width modulated signal having a set logic state and a reset logic state;
a second terminal adapted to be configured as a reference ground terminal;
a third terminal adapted to be configured as an output terminal of the gate driving unit for providing a switch driving signal having a logic state including a driving set logic state and a driving reset logic state; and
a reporting terminal, configured to provide a reporting signal; wherein
the gate driving unit is configured to detect or monitor a current signal flowing through the third terminal, and further configured to adjust the fault reporting signal based on the current signal.

36. The gate driving unit of claim 35, wherein the gate driving unit is further configured to set the reporting signal to a first report status during normal operation.

37. The gate driving unit of claim 35, wherein the gate driving unit is further configured to set the reporting signal to a second report status when a situation of substantially non-ZVS is identified.

38. The gate driving unit of claim 35, wherein the gate driving unit is further configured to set the reporting signal to a third report status when a short circuit event is detected.

39. The gate driving unit of claim 37, wherein:
the gate driving unit is further configured to determine that the situation of substantially non-ZVS is identified if a moment when a first detection event indicative of the current signal flowing out of the third terminal and then falling substantially at zero is identified during the switch driving signal at the driving reset logic state is ahead of a moment when the pulse width modulated signal is changed from the reset logic state to the set logic state during a switching cycle of the switch driving signal, or
if a second detection event indicative of the current signal is flowing into the third terminal is identified after the first detection event has been identified during the switching cycle of the switch driving signal, or
if the first detection event has not been identified until a maximum detection time period expires since a moment when the pulse width modulated signal is changed from the reset logic state to the set logic state.

40. The gate driving unit of claim 38, wherein the gate driving unit is further configured to determine that the short circuit event is detected if the current signal is flowing into the third terminal for a predetermined short circuit detection time during the switch driving signal is at the driving set logic state or if a voltage on the third terminal is higher than a first supply voltage on a fourth terminal of the gate driving unit during the switch driving signal is at the driving set logic state.

41. The gate driving unit of claim 35, wherein the gate driving unit is further configured to control the logic state of the switch driving signal based on the pulse width modulated signal and the current signal.

42. The gate driving unit of claim 41, wherein the gate driving unit is further configured to reset the switch driving signal at the driving reset logic state when the pulse width modulated signal is changed from the set logic state to the reset logic state.

43. The gate driving unit of claim 41, wherein:
the gate driving unit is further configured to set the switch driving signal at the driving set logic state if a first detection event indicative of the current signal flowing out of the third terminal and then falling substantially at zero has been identified during a first detection time window and the pulse width modulated signal is at the set logic state, and wherein
the first detection time window has a first window width and is enabled or set during the switch driving signal is at the driving reset logic state.

44. The gate driving unit of claim 41, wherein:
the gate driving unit is further configured to force the switch driving signal to be set at the driving set logic state if a first detection event indicative of the current signal flowing out of the third terminal and then falling substantially at zero has neither been identified during a first detection time window nor been identified until a maximum detection time period expires since a moment when the pulse width modulated signal is changed from the reset logic state to the set logic state; and wherein
the first detection time window has a first window width and is enabled or set during the switch driving signal is at the driving reset logic state.

45. The gate driving unit of claim 35, further comprising:
a temperature sensing input terminal, adapted to be configured to detect a temperature reading signal; wherein
the gate driving unit is further configured to provide a temperature report signal having a pulse width modulated by the temperature reading signal; and wherein
the gate driving unit is further configured to set the reporting signal to the first report status embodied as the temperature report signal during normal operation.

46. The gate driving unit of claim 35, wherein
the gate driving unit is further configured to determine that a short circuit event is detected if the current signal is flowing into the third terminal for a predetermined short circuit detection time during the switch driving signal is at the driving set logic state, or if a voltage on the third terminal goes higher than a first supply voltage on a fourth terminal of the gate driving unit during the switch driving signal is at the driving set logic state; and wherein
the gate driving unit is further configured to reset the switch driving signal at the driving reset logic state when the short circuit event is detected.
